(19) United States
(12) Patent Application Publication
(10) Pub. No.: US 2015/0173226 A1
(43) Pub. Date: Jun. 18, 2015

(54) DISPLAY APPARATUS

(71) Applicant: Sharp Kabushiki Kaisha, Osaka (JP)

(72) Inventors: Kazuya Murakami, Osaka (JP); Atsushi Sugimoto, Yonago-shi (JP)

(73) Assignee: SHARP KABUSHIKI KAISHA, Osaka (JP)

(21) Appl. No.: 14/419,784

(22) PCT Filed: Aug. 1, 2013
(86) PCT No.: PCT/JP2013/070835

§ 371 Date: Feb. 5, 2015

(30) Foreign Application Priority Data
Aug. 6, 2012 (JP) 2012-174186

(51) Int. Cl. H05K 5/06; H05K 5/02; H05K 5/00

(52) U.S. Cl. CPC H05K 5/063; H05K 5/0017; H05K 5/0213

(57) ABSTRACT

Condensation is prevented in a space between a protective panel, a touch panel, or the like and a display surface of a display unit, and penetration is effectively prevented of foreign matter into the space between the protective panel, the touch panel, or the like and the display surface of the display unit from outside. A display device is provided with a display unit, a protective panel, and a sealing member. The display unit has a display surface that causes data to be displayed. The protective portion is disposed so as to cover the display surface. The sealing member is provided between the display unit and the protective portion so as to surround the display surface in a plan view seen from above the display surface, and is provided so as to form a path connecting an inner region surrounded by the sealing member to a region outside the sealing member with a shape that is not linear.

### TECHNICAL FIELD

The present invention relates to a display device provided with a protective panel, a touch panel, and the like.

### BACKGROUND ART

There are display devices in which a protective panel that uses a transparent member or the like to protect a display surface of a display unit from shocks, dirt, and the like is installed on a display-surface-side of the display unit. There are also display devices in which a touch panel is installed on the display-surface-side of the display unit.

With this type of display device, the protective panel or the touch panel is generally adhered and secured to the display-surface-side of the display unit with a sealing member disposed on circumferential sides of the display surface of the display unit.

FIG. 14 is a view showing a schematic configuration of a display unit 91, a sealing member 92, and a protective panel 93 in a conventional display device 900. Furthermore, FIG. 15 is a plan view showing a positional relationship between the display unit 91 and the sealing member 92 of the display device 900.

For example, with the display device disclosed in Patent Document 1, the sealing member 92 is disposed so as to surround a display surface 911 of the display unit 91, and is disposed such that ventilation holes 941 and 942 are formed such that an inner region surrounded by the sealing member 92 and an outer region are partially connected, as shown in FIGS. 14 and 15.

By disposing the sealing member 92 in this manner and adhering and securing the display unit 91 and the protective panel 93, condensation can be prevented and entry of foreign matter from outside can be prevented. In other words, by disposing the sealing member 92 as described above, ventilation is maintained by the ventilation holes 941 and 942, and therefore water vapor does not readily remain in a space between the display surface 911 and the protective panel 93, and even in a case in which the temperature suddenly rises, condensation does not readily form between the display unit 91 and the protective panel 93. Furthermore, by disposing the sealing member 92 as described above, only the ventilation holes 941 and 942 are a path connecting an inside and an outside of the space between the protective panel 93 and the display surface 911 surrounded by the sealing member 92, making it possible to prevent entry of foreign matter from outside into the space between the display surface 911 and the protective panel 93.

### RELATED ART DOCUMENT

### Patent Document

Patent Document 1: Japanese Patent Application Laid-Open Publication No. 2008-89857

### SUMMARY OF THE INVENTION

### Problems to be Solved by the Invention

However, with the display device disclosed in Patent Document 1, the ventilation holes 941 and 942 are straight paths in a plan view, and dirt, dust, and other foreign matter that has a smaller width than an entrance (or exit) of the ventilation hole (or area than an entrance (or exit) of the ventilation hole) sometimes penetrates the space between the display unit 91 and the protective panel 93 from outside.

Accordingly, the present invention has as a purpose, in light of these problems, to realize a display device that prevents condensation in a space between a protective panel, a touch panel, or the like and a display surface of a display unit, and effectively prevents penetration of foreign matter into the space between the protective panel, the touch panel, or the like and the display surface of the display unit from outside.

### Means for Solving the Problems

To solve the aforementioned problems, a display device of a first configuration is provided with a display unit, a protective portion, and a sealing member. The display unit has a display surface that causes data to be displayed. The protective portion is disposed so as to cover the display surface. The sealing member is provided between the display unit and the protective portion, is provided so as to surround the display surface in a plan view seen from above the display surface, and is provided so as to form a path connecting an inner region surrounded by the sealing member and a region outside the sealing member with a shape that is not linear.

With this display device, ventilation can thus be ensured between the protective portion and the display unit and in a space outside the sealing member, and therefore condensation in the space between the protective portion and the display unit can be prevented. Moreover, with this display device, the inner region surrounded by the sealing member and the outer region are connected by the sealing member in a path that has a shape that is not linear, and therefore penetration of foreign matter into the space between the display unit and the protective portion can be effectively prevented.

Note that the “protective portion” may be a touch panel (e.g., a capacitive touch panel).

A display device of a second configuration is the first configuration, wherein the display surface is rectangular, wherein the sealing member includes a first sealing member, a second sealing member, a third sealing member, and a fourth sealing member disposed outside respective edges of four edges of the display surface in a plan view seen from above the display surface, and wherein, in at least one space of a space between the first sealing member and the second sealing member, a space between the second sealing member and the third sealing member, a space between the third sealing member and the fourth sealing member, and a space between the fourth sealing member and the first sealing member in a plan view seen from above the display surface, the path has a shape that bends twice at a right angle so as to connect, to the outer region, the inner region surrounded by the first sealing member, the second sealing member, the third sealing member, and the fourth sealing member.

With this display device, the outer region and the inner region surrounded by the sealing member are connected by a more complex path; that is, the outer region and the inner region surrounded by the sealing member are connected by a path that has a shape which bends at a right angle twice in a plan view, and therefore condensation can be prevented in the space between the protective portion and the display unit, and foreign matter can be effectively prevented from entering the space between the protective portion and the display unit from outside.

Note that “right angle” is a concept including substantially right angles, and is a concept which tolerates design error and the like.

A display device of a third configuration is the first configuration, wherein the sealing member includes a first sealing member, a second sealing member, a third sealing member, and a fourth sealing member disposed outside respective edges of four edges of the display surface in a plan view seen from above the display surface, and wherein, in at least one space of a space between the first sealing member and the second sealing member, a space between the second sealing member and the third sealing member, a space between the third sealing member and the fourth sealing member, and a space between the fourth sealing member and the first sealing member in a plan view seen from above the display surface, the path has a shape that bends an odd number of times at an acute angle as to connect, to the outer region, the inner region surrounded by the first sealing member, the second sealing member, the third sealing member, and the fourth sealing member.

With this display device, the outer region and the inner region surrounded by the sealing member are connected by a more complex path; that is, the outer region and the inner region surrounded by the sealing member are connected by a path that has a shape that bends at an odd angle an odd number of times in a plan view, and therefore condensation can be prevented in the space between the protective portion and the display unit, and foreign matter can be effectively prevented from entering the space between the protective portion and the display unit from outside.

A display device of a fourth configuration is the first configuration, wherein the display surface is rectangular, wherein the sealing member includes a first sealing member, a second sealing member, a third sealing member, and a fourth sealing member disposed outside respective edges of four edges of the display surface in a plan view seen from above the display surface, wherein a first end of the first sealing member is disposed near a second end of the second sealing member, wherein a first end of the second sealing member is disposed near a second end of the third sealing member, wherein a first end of the third sealing member is disposed near a second end of the fourth sealing member, wherein a first end of the fourth sealing member is disposed near a second end of the first sealing member, and wherein at least one of the following is satisfied:

(1) the first sealing member has a substantially trapezoidal cut-out portion in an end region of the first end, and the second sealing member has a triangular cut-out portion in a region facing the substantially trapezoidal cut-out portion of the first sealing member;

(2) the second sealing member has a substantially trapezoidal cut-out portion in an end region of the first end, and the third sealing member has a triangular cut-out portion in a region facing the substantially trapezoidal cut-out portion of the second sealing member;

(3) the third sealing member has a substantially trapezoidal cut-out portion in an end region of the first end, and the fourth sealing member has a triangular cut-out portion in a region facing the substantially trapezoidal cut-out portion of the third sealing member; and

(4) the fourth sealing member has a substantially trapezoidal cut-out portion in an end region of the first end, and the first sealing member has a triangular cut-out portion in a region facing the substantially trapezoidal cut-out portion of the fourth sealing member.

A display device of a fifth configuration is the first configuration, wherein the sealing member is provided so as to surround the display surface in a plan view seen from above the display surface and to form the path so as to connect, in a substantially arc-like shape, the inner region surrounded by the sealing member to the outer region outside the sealing member.

A display device of a sixth configuration is the first configuration, wherein the sealing member is provided so as to surround the display surface in a plan view seen from above the display surface and to form the path so as to connect, in a substantially “S”-like shape, the inner region surrounded by the sealing member to the outer region outside the sealing member.

A display device of a seventh configuration is the first configuration, wherein the display surface is rectangular, wherein the sealing member includes a first sealing member, a second sealing member, a third sealing member, and a fourth sealing member disposed outside respective edges of four edges of the display surface in a plan view seen from above the display surface, wherein a first end of the first sealing member is disposed near a second end of the second sealing member, wherein a first end of the second sealing member is disposed near a second end of the third sealing member, wherein a first end of the third sealing member is disposed near a second end of the fourth sealing member, wherein a first end of the fourth sealing member is disposed near a second end of the first sealing member, and wherein at least one of the following is satisfied:

(1) the first sealing member has a substantially rectangular cut-out portion in an end region of the first end, and the second sealing member has a semielliptical cut-out portion in a region facing the substantially rectangular cut-out portion of the first sealing member;

(2) the second sealing member has a substantially rectangular cut-out portion in an end region of the first end, and the third sealing member has a semielliptical cut-out portion in a region facing the substantially rectangular cut-out portion of the second sealing member;

(3) the third sealing member has a substantially rectangular cut-out portion in an end region of the first end, and the fourth sealing member has a semielliptical cut-out portion in a region facing the substantially rectangular cut-out portion of the third sealing member; and

(4) the fourth sealing member has a substantially rectangular cut-out portion in an end region of the first end, and the first sealing member has a semielliptical cut-out portion in a region facing the substantially rectangular cut-out portion of the fourth sealing member.

A display device of an eighth configuration is any one of the first to seventh configurations, wherein the display surface is rectangular, wherein the sealing member includes a first sealing member, a second sealing member, a third sealing member, and a fourth sealing member disposed outside respective edges of four edges of the display surface in a plan view seen from above the display surface, wherein, in at least one space of a space between the first sealing member and the second sealing member, a space between the second sealing member and the third sealing member, a space between the third sealing member and the fourth sealing member, and a space between the fourth sealing member and the first sealing member in a plan view seen from above the display surface, the path connects, to the outer region, the inner region surrounded by the first sealing member, the second sealing member, the third sealing member, and the fourth sealing member, and wherein when a first width is a width of a first position at which the path is connected to the inner region surrounded by the first sealing member, the second sealing member, the third sealing member, and the fourth sealing member, and when a second width is a width of a second position at which the path is connected to the outer region surrounded by the first sealing member, the second sealing member, the third sealing member, and the fourth sealing member in a plan view seen from above the display surface, the path has a width that is greater than whichever of the first width or the second width is wider in at least one portion between the first position and the second position in a plan view seen from above the display surface.

Thus, with this display device, a region in which foreign matter can easily collect is provided to a portion along the path connecting the inner region surrounded by the sealing member and the outer region in a plan view. Accordingly, with this display device, condensation can be prevented in a space between the protective portion and the display unit, and penetration of foreign matter into the space between the display unit and the protective portion from outside can be effectively prevented by causing foreign matter penetrating from the outside to collect in the portion along the path connecting the inner region surrounded by the sealing member and the outer region.

### Effects of the Invention

With the present invention, a display device that prevents condensation in a space between a protective panel, a touch panel, or the like and a display surface of a display unit, and effectively prevents penetration of foreign matter into the space between the protective panel, the touch panel, or the like and the display surface of the display unit from outside can be realized.

### BRIEF DESCRIPTION OF THE DRAWINGS

FIG. 1 is a view of a schematic configuration of a display device 1000 according to Embodiment 1.

FIG. 2 is plan view showing a schematic configuration of the display device 1000 according to Embodiment 1.

FIG. 3 is an enlarged view of a region AR1 of a plan view showing a schematic configuration of the display device 1000 according to Embodiment 1.

FIG. 4 is plan view showing a schematic configuration of a display device according to Embodiment 2.

FIG. 5 is an enlarged view of a region AR2 of a plan view showing a schematic configuration of the display device according to Embodiment 2.

FIG. 6 is an enlarged view of a region of one part of a plan view showing a schematic configuration of a display device according to Modification Example 1 of Embodiment 2.

FIG. 7 is an enlarged view of a region of one part of a plan view showing a schematic configuration of a display device according to Modification Example 2 of Embodiment 2.

FIG. 8 is an enlarged view of a region of one part of a plan view showing a schematic configuration of a display device according to Modification Example 3 of Embodiment 2.

FIG. 9 is an enlarged view of a region of one part of a plan view showing a schematic configuration of a display device according to Modification Example 4 of Embodiment 2.

FIG. 10 is an enlarged view of a region of one part of a plan view showing a schematic configuration of a display device according to Modification Example 5 of Embodiment 2.

FIG. 11 is a schematic configuration of a display device according to another embodiment.

FIG. 12 is an enlarged view of a region of one part of a plan view showing a schematic configuration of a display device according to another embodiment.

FIG. 13 is an enlarged view of a region of one part of a plan view showing a schematic configuration of a display device according to another embodiment.

FIG. 14 is a schematic configuration of a conventional display device.

FIG. 15 is a plan view showing a schematic configuration of a conventional display device.

### DETAILED DESCRIPTION OF EMBODIMENTS

### Embodiment 1

Embodiment 1 of the present invention is described below, with reference to the drawings.

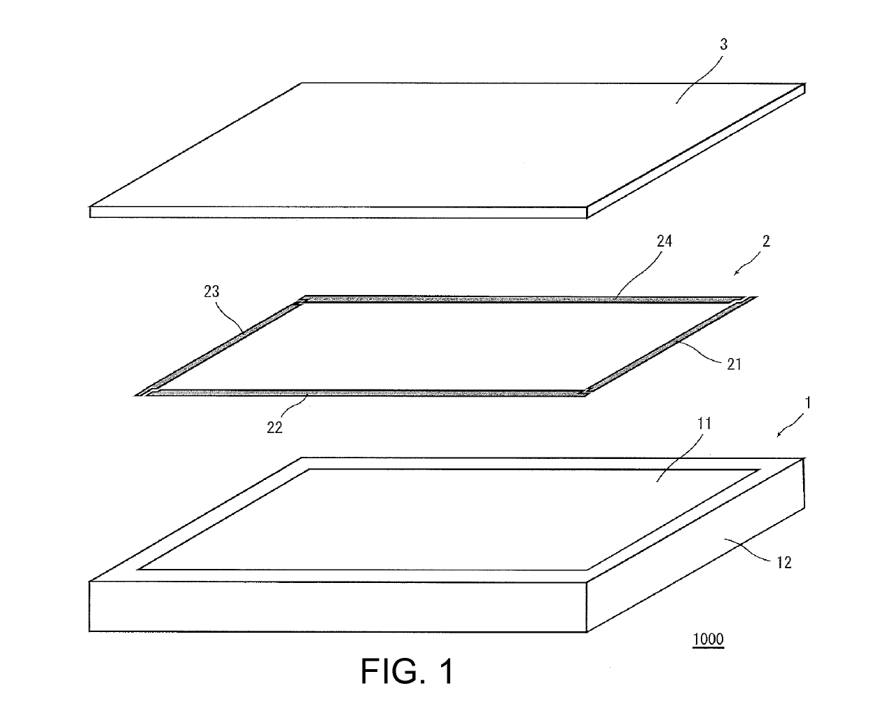

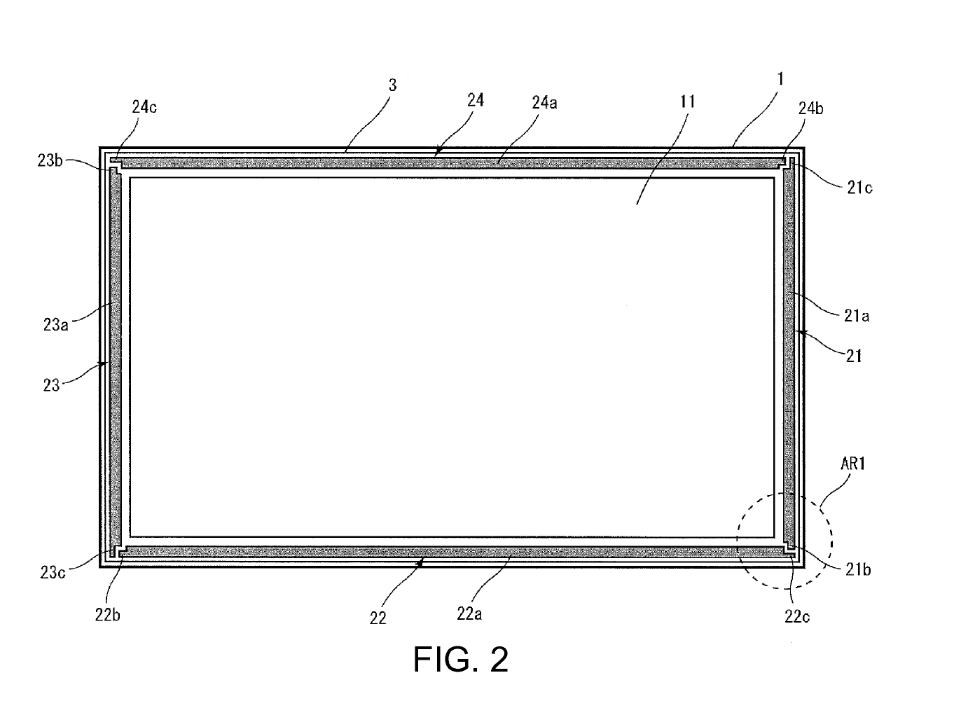

FIG. 1 is a schematic view showing a configuration of a display device 1000 according to Embodiment 1. Furthermore, FIG. 2 is a plan view showing a schematic configuration of the display device 1000 (plan view seen from above a display surface 11 of the display device 1000).

The display device 1000 is provided with a display unit 1, which includes the display surface 11 that displays data, a sealing member 2 that is disposed between the display unit 1 and a protective panel 3 in order to adhere and secure the display unit 1 and the protective panel 3, and the protective panel 3 disposed so as to cover the display surface of the display unit 1 in order to protect the display surface 11 of the display unit 1.

The display unit 1 is formed by fitting and securing a liquid crystal panel, an organic EL panel, or the like into a display unit frame 12. Note that, as shown in FIG. 1, the liquid crystal panel, the organic EL panel, or the like is fitted and secured into the display unit frame 12 such that the display surface 11 of the liquid crystal panel, the organic EL panel, or the like is disposed in an open portion of the display unit frame 12.

The sealing member 2 is disposed between the display unit 1 and the protective panel 3 in order to adhere and secure the display unit 1 and the protective panel 3 to each other. The sealing member 2 includes a first sealing member 21, a second sealing member 22, a third sealing member 23, and a fourth sealing member 24. The first sealing member 21, the second sealing member 22, the third sealing member 23, and the fourth sealing member 24 are disposed so as to surround the display surface 11 of the display unit 1, as shown in FIGS. 1 and 2. Note that double-sided tape or a material having adhesive properties (urethane, rubber, sponges, and so on having adhesive properties) is used, for example, as the first sealing member 21, the second sealing member 22, the third sealing member 23, and the fourth sealing member 24.

The first sealing member 21 is formed from a rectangular portion 21a which has an elongated shape, a first extended portion 21b, and a second extended portion 21c, as shown in FIG. 2. The first extended portion 21b has a width that is shorter than a width of the rectangular portion 21a, and is formed such that one side from a first end in a lengthwise direction of the rectangular portion 21a extends in the lengthwise direction of the rectangular portion 21a, matching a first side in the lengthwise direction of the rectangular portion 21a. The second extended portion 21c has a width that is shorter than a width of the rectangular portion 21a, and is formed such that one side from a second end in a lengthwise direction of the rectangular portion 21a extends in the lengthwise direction of the rectangular portion 21a, matching the first side in the lengthwise direction of the rectangular portion 21a.

The second sealing member 22 is formed from a rectangular portion 22a that has an elongated shape, a first extended portion 22b, and a second extended portion 22c, as shown in FIG. 2. The first extended portion 22b has a width that is shorter than a width of the rectangular portion 22a, and is formed such that one side from a first end in a lengthwise direction of the rectangular portion 22a extends in the lengthwise direction of the rectangular portion 22a, matching a first side in the lengthwise direction of the rectangular portion 22a. The second extended portion 22c has a width that is shorter than a width of the rectangular portion 22a, and is formed such that one side from a second end in a lengthwise direction of the rectangular portion 22a extends in the lengthwise direction of the rectangular portion 22a, matching the first side in the lengthwise direction of the rectangular portion 22a.

The third sealing member 23 is formed from a rectangular portion 23a that has an elongated shape, a first extended portion 23b, and a second extended portion 23c, as shown in FIG. 2, and the third sealing member has the same shape as the first sealing member 21. In other words, the rectangular portion 23a of the third sealing member 23 has the same shape as the rectangular portion 21a of the first sealing member 21, the first extended portion 23b of the third sealing member 23 has the same shape as the first extended portion 21b of the first sealing member 21, and the second extended portion 23c of the third sealing member 23 has the same shape as the second extended portion 21c of the first sealing member 21.

The fourth sealing member 24 is formed from a rectangular portion 24a that has an elongated shape, a first extended portion 24b, and a second extended portion 24c, as shown in FIG. 2, and the fourth sealing member has the same shape as the second sealing member 22. In other words, the rectangular portion 24a of the fourth sealing member 24 has the same shape as the rectangular portion 22a of the second sealing member 22, the first extended portion 24b of the fourth sealing member 24 has the same shape as the first extended portion 22b of the second sealing member 22, and the second extended portion 24c of the fourth sealing member 24 has the same shape as the second extended portion 22c of the second sealing member 22.

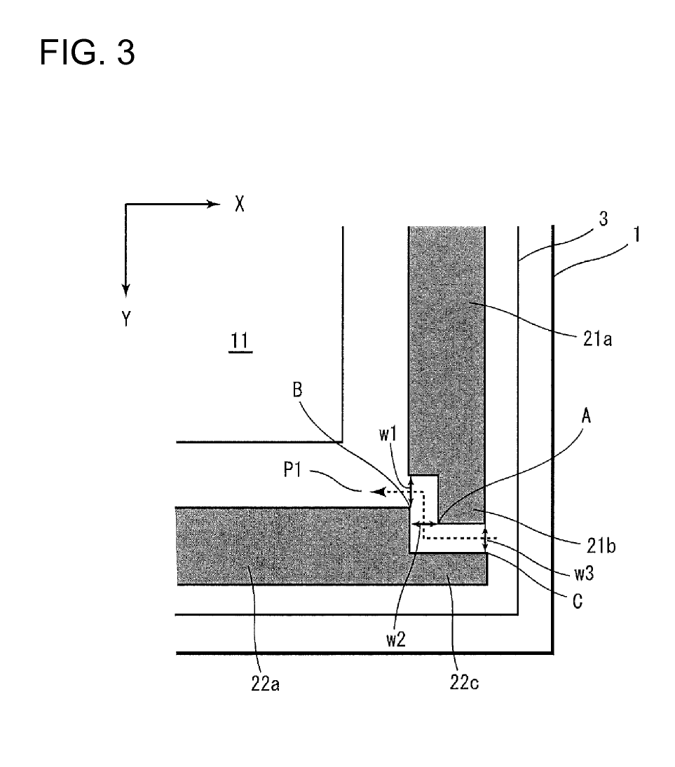

An arrangement of the first sealing member 21 and the second sealing member 22 is described using FIG. 3.

FIG. 3 is an enlarged view of a region AR1 in FIG. 2. Note that for the sake of simplicity of description, an X-axis and a Y-axis are set, as shown in FIG. 3, with a rightward direction being a positive direction of the X-axis and a downward direction being a positive direction of the Y-axis.

As shown in FIG. 3, an endpoint of the first extended portion of the first sealing member 21 towards the display surface 11 is point A, an endpoint of the second sealing member 22 towards the display surface 11 is point B, and an endpoint of the second extended portion 22c of the second sealing member 22 toward the first sealing member 21 is point C. Furthermore, an X coordinate of the point A is X(A), a Y coordinate of an endpoint A is Y(A), an X coordinate of the point B is X(B), a Y coordinate of an endpoint B is Y(B), an X coordinate of point C is X(C), and a Y coordinate of an endpoint C is Y(C).

As shown in FIG. 3, the first sealing member 21 is disposed such that the Y coordinate position (Y(A)) of an end portion of the first extended portion 21b towards the second sealing member 22 is greater than the Y coordinate position (Y(B)) of a side of the rectangular portion 22a of the second sealing member 22 towards the display surface 11.

Furthermore, as shown in FIG. 3, the second sealing member 22 is disposed such that the X coordinate position (X(C)) of an end portion of the second extended portion 22c toward the first sealing member 21 is greater than the X coordinate position (X(A)) of a side of the first extended portion 21b of the first sealing member 21 towards the display surface 11.

By disposing the first sealing member 21 and the second sealing member 22 as described above, a ventilation hole having a path P1 in which a direction changes in two places (the path P1 in which a direction along a center line of the path changes 90 degrees in two places) is formed, as shown in FIG. 3. In other words, by disposing the first sealing member 21 and the second sealing member 22 as described above, the path P1 of the ventilation hole, which connects an inner region (toward the display surface 11) of the sealing member 2 and a region outside the sealing member 2, can be formed such that the direction of the center line thereof changes in two places.

Note that a ventilation hole formed between the second sealing member 22 and the third sealing member 23 (the ventilation hole in a bottom left portion of FIG. 2), a ventilation hole formed between the third sealing member 23 and the fourth sealing member 24 (the ventilation hole formed in a top left portion of FIG. 2), and a ventilation hole formed between the fourth sealing member 24 and the first sealing member 21 (the ventilation hole in a top right portion of FIG. 2) are the same as the ventilation hole formed by the first sealing member 21 and the second sealing member 22 described above (the ventilation hole in a bottom right portion of FIG. 2).

Furthermore, as shown in FIG. 2, the first sealing member 21 is disposed such that the second extended portion 21c is disposed above and the first extended portion 21b is disposed below in a rightward outer region of the display surface 11.

Furthermore, as shown in FIG. 2, the second sealing member 22 is disposed such that the first extended portion 22b is disposed to the left and the second extended portion 22c is disposed to the right in a bottom outer region of the display surface 11.

Furthermore, as shown in FIG. 2, the third sealing member 23 is disposed such that the first extended portion 23b is disposed above and the second extended portion 23c is disposed below in a leftward outer region of the display surface 11.

Furthermore, as shown in FIG. 2, the fourth sealing member 24 is disposed such that the first extended portion 24b is disposed to the right and the second extended portion 24c is disposed to the left in a top outer region of the display surface 11.

Note that the first sealing member 21, the second sealing member 22, the third sealing member 23, and the fourth sealing member 24 are preferably disposed such that widths of the ventilation holes (a value of Y(C)−Y(A) or a value of X(A)−X(B) in FIG. 3) are in a range of 0 to 1 mm. For example, the first sealing member 21 and the second sealing member 22 are preferably disposed such that, in FIG. 3, a width w1 is 0.5 mm, a width w2 is 0.5 mm, and a width w3 is 0.5 mm.

The protective panel 3 is disposed so as to cover the display surface of the display unit 1 in order to protect the display surface 11 of the display unit 1. The protective panel 3 is formed from a plate-shaped transparent member, for example, in order to protect the display surface 11 of the display unit 1 from shocks, dust, and the like. Furthermore, the protective panel 3 may be a touch panel (e.g., a capacitive touch panel).

Thus, with the display device 1000, the first sealing member 21, the second sealing member 22, the third sealing member 23, and the fourth sealing member 24, which have a rectangular portion, a first extended portion, and a second extended portion, are disposed so as to surround the display surface 11, and are disposed such that gaps having a shape that is not linear in a plan view are created between the first sealing member 21, the second sealing member 22, the third sealing member 23, and the fourth sealing member 24, respectively. Thus, with the display device 1000, the inner region surrounded by the sealing member 2 (a region on the display surface 11 side) and the outer region can be connected by the ventilation holes of paths that are not linear in a plan view, and therefore condensation in a space between the protective panel 3 and the display surface 11 of the display unit 1 can be prevented. Furthermore the display device 1000 has the ventilation holes with paths that are not rectilinear in a plan view and that connect the inner region (the region towards the display surface 11) and the outer region, and therefore entry of foreign matter such as dust, dirt, and the like that is smaller than a width of an entry (or exit) of the ventilation holes (or an area of an entrance (or an exit) of the ventilation holes) into the space between the display unit 1 and the protective panel 3 from outside can effectively be prevented.

### Embodiment 2

Embodiment 2 is described next.

In Embodiment 2, a shape of sealing member is different from Embodiment 1. Aside from this, Embodiment 2 is the same as Embodiment 1. Note that in the present embodiment, portions that are the same as in the above embodiment are given the same reference characters and detailed descriptions thereof are omitted.

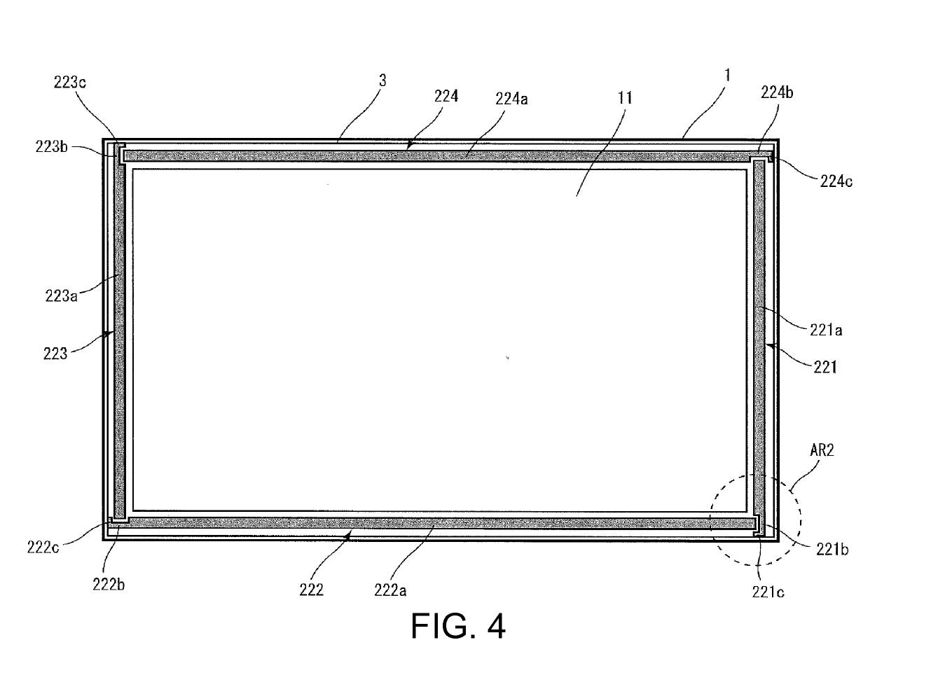

A sealing member of the present embodiment includes a first sealing member 221, a second sealing member 222, a third sealing member 223, and a fourth sealing member 224, as shown in FIG. 4.

The first sealing member 221 is formed from a rectangular portion 221a that has an elongated shape, a first extended portion 221b that extends in a lengthwise direction from the rectangular portion 221a, and a second extended portion 221c that extends in the lengthwise direction of the rectangular portion 221a with substantially the same width as the rectangular portion 221a from an end portion on an opposite side of the rectangular portion 221a from the first extended portion 221b, as shown in FIG. 4.

The first extended portion 221b has a width that is shorter than a width of the rectangular portion 221a, and is formed such that one side from a first end in a lengthwise direction of the rectangular portion 221a extends in the lengthwise direction of the rectangular portion 221a, matching a first side in the lengthwise direction of the rectangular portion 221a.

The second sealing member 222 is formed from a rectangular portion 222a that has an elongated shape, a first extended portion 222b that extends in a lengthwise direction from the rectangular portion 222a, and a second extended portion 222c that extends in the lengthwise direction of the rectangular portion 222a with substantially the same width as the rectangular portion 222a from an end portion on an opposite side of the rectangular portion 222a from the first extended portion 222b, as shown in FIG. 4.

The first extended portion 222b has a width that is shorter than a width of the rectangular portion 222a, and is formed such that one side from a first end in a lengthwise direction of the rectangular portion 222a extends in the lengthwise direction of the rectangular portion 222a, matching a first side in the lengthwise direction of the rectangular portion 222a.

The third sealing member 223 is formed from a rectangular portion 223a that has an elongated shape, a first extended portion 223b, and a second extended portion 223c, as shown in FIG. 4, having the same shape as the first sealing member 221. In other words, the rectangular portion 223a of the third sealing member 223 has the same shape as the rectangular portion 221a of the first sealing member 221, the first extended portion 223b of the third sealing member 223 has the same shape as the first extended portion 221b of the first sealing member 221, and the second extended portion 223c of the third sealing member 223 has the same shape as the second extended portion 221c of the first sealing member 221.

The fourth sealing member 224 is formed from a rectangular portion 224a that has an elongated shape, a first extended portion 224b, and a second extended portion 224c, as shown in FIG. 4, having the same shape as the second sealing member 222. In other words, the rectangular portion 224a of the fourth sealing member 224 has the same shape as the rectangular portion 222a of the second sealing member 222, the first elongated portion 224b of the fourth sealing member 224 has the same shape as the first elongated portion 222b of the second sealing member 222, and the second elongated portion 224c of the fourth sealing member 224 has the same shape as the second elongated portion 222c of the second sealing member 222.

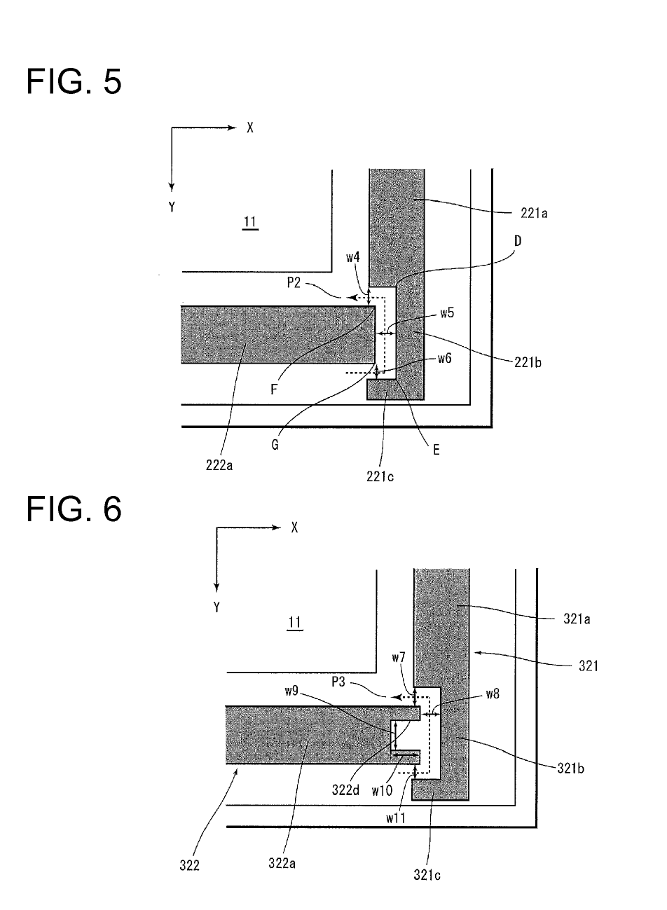

An arrangement of the first sealing member 221 and the second sealing member 222 is described using FIG. 5.

FIG. 5 is an enlarged view of a region AR2 in FIG. 4. Note that for the sake of simplicity of description, an X-axis and a Y-axis are set as shown in FIG. 5, with a rightward direction being a positive direction of the X-axis and a downward direction being a positive direction of the Y-axis.

As shown in FIG. 5, an endpoint of the first extended portion 221b of the first sealing member 221 towards the display surface 11 and the rectangular portion 221a is a point D, and an endpoint of the first extended portion 221b towards the display surface 11 and the second extended portion 221c is a point E. Furthermore, as shown in FIG. 5, an endpoint of the second sealing member 222 towards the display surface 11 and the first sealing member 221 is a point F, and an endpoint of the second sealing member 222 away from the display surface 11 and towards the first sealing member 221 is a point G. Furthermore, an X coordinate of an endpoint a is indicated as X(α), and a Y coordinate of the endpoint a is indicated as Y(α).

The first sealing member 221 and the second sealing member 222 are disposed, as shown in FIG. 5, such that the Y coordinate (Y(D)) of the endpoint D is smaller than the Y coordinate (Y(F)) of the endpoint F, and such that the Y coordinate (Y(E)) of the endpoint E is greater than the Y coordinate (Y(G)) of the endpoint G. Furthermore, the first sealing member 221 and the second sealing member 222 are disposed, as shown in FIG. 5, such that the X coordinate (X(D)) of the endpoint D is smaller than the X coordinate (X(F)) of the endpoint F, and such that the X coordinate (X(E)) of the endpoint E is greater than the X coordinate (X(G)) of the endpoint G.

In other words, the first sealing member 221 and the second sealing member 222 are disposed so as to meet conditions according to four inequalities below.

Y(D)<Y(F)

Y(G)<Y(E)

X(F)<X(D)

X(G)<X(E)

By disposing the first sealing member 221 and the second sealing member 222 as described above, a ventilation hole having a path P2 in which a direction changes in two places (the path P2 in which a direction along a center line of the path changes 90 degrees in two places) is formed, as shown in FIG. 5. In other words, by disposing the first sealing member 221 and the second sealing member 222 as described above, the path P2 of the ventilation hole, which connects an inner region (toward the display surface 11) of the sealing member 2 and a region outside the sealing member 2, can be formed such that the direction of the center line thereof changes in two places.

Note that a ventilation hole formed between the second sealing member 222 and the third sealing member 223 (the ventilation hole in a bottom left portion of FIG. 4), a ventilation hole formed between the third sealing member 223 and the fourth sealing member 224 (the ventilation hole formed in a top left portion of FIG. 4), and a ventilation hole formed between the fourth sealing member 224 and the first sealing member 221 (the ventilation hole in a top right portion of FIG. 4) are the same as the ventilation hole formed by the first sealing member 221 and the second sealing member 222 described above (the ventilation hole in a bottom right portion of FIG. 4).

Furthermore, as shown in FIG. 4, the first sealing member 221 is disposed such that the first extended portion 221b and the second extended portion 221c are disposed below in a rightward outer region of the display surface 11.

Furthermore, as shown in FIG. 4, the second sealing member 222 is disposed such that the first extended portion 222b and the second extended portion 222c are disposed to the left in a bottom outer region of the display surface 11.

Furthermore, as shown in FIG. 4, the third sealing member 223 is disposed such that the first extended portion 223b and the second extended portion 223c are disposed above in a leftward outer region of the display surface 11.

Furthermore, as shown in FIG. 4, the fourth sealing member 224 is disposed such that the first extended portion 224b and the second extended portion 224c are disposed to the right in a top outer region of the display surface 11.

Note that the first sealing member 21, the second sealing member 22, the third sealing member 23, and the fourth sealing member 24 are preferably disposed such that widths of the ventilation holes are in a range of 0 to 1 mm. For example, the first sealing member 21 and the second sealing member 22 are preferably disposed such that, in FIG. 5, a width w4 is 0.5 mm, a width w5 is 0.5 mm, and a width w6 is 0.5 mm.

Thus, with the display device of the present embodiment, the first sealing member 221, the second sealing member 222, the third sealing member 223, and the fourth sealing member 224, which each have a rectangular portion, a first extended portion, and a second extended portion, are disposed so as to surround the display surface 11, and are disposed such that gaps having a shape that is not linear in a plan view are created between the first sealing member 221, the second sealing member 222, the third sealing member 223, and the fourth sealing member 224, respectively. Thus, with the display device of the present embodiment, the inner region surrounded by the sealing member 2 (a region towards the display surface 11) and the outer region can be connected by the ventilation holes of paths that are not linear in a plan view, and therefore condensation in a space between the protective panel 3 and the display surface 11 of the display unit 1 can be prevented. Furthermore the display device of the present embodiment has the ventilation holes with paths that are not linear in a plan view and that connect the inner region (the region towards the display surface 11) and the outer region, and therefore entry of foreign matter such as dust, dirt, and the like that is smaller than a width of an entry (or exit) of the ventilation holes (or an area of an entrance (or an exit) of the ventilation holes) into the space between the display unit 1 and the protective panel 3 from outside can effectively be prevented.

### Modification Example 1

Modification Example 1 of the present embodiment is described next. Note that detailed descriptions are omitted for portions which are the same as in the above embodiment.

A display device of the present variation has a configuration in which in the display device of Embodiment 2 the first sealing member 221 is replaced by a first sealing member 321, the second sealing member 222 is replaced with a second sealing member 322, the third sealing member 223 is replaced with a third sealing member 323, and the fourth sealing member 224 is replaced with a fourth sealing member 324, respectively. Aside from this, the display device of the present variation is the same as the display device of Embodiment 2.

Like FIG. 5, FIG. 6 is an enlarged view of a bottom right end portion in a plan view seen from above a display surface 11 of a display unit 1, and is a view in which a vicinity of end portions of the first sealing member 321 and the second sealing member 322 of the present variation are shown enlarged.

As shown in FIG. 6, the second sealing member 322 of the display device of the present modification example has a shape provided with a cut-out portion 322d on an end of the rectangular portion 222a of the second sealing member 222 of the display device of Embodiment 2 towards the first sealing member 221. Furthermore, three end faces forming the cut-out portion 322d are glue end faces formed from a substance having adhesive properties.

The first sealing member 321, the third sealing member 323, and the fourth sealing member 324 of the display device of the present modification example also have a shape provided with a cut-out portion like the second sealing member 322 described above. Thus, a shape of a path in a plan view of ventilation holes formed between the second sealing member 322, the third sealing member 323, the fourth sealing member 324, and the first sealing member 321 is the same as the shape shown in FIG. 6.

The first sealing member 321 of the display device of the present modification example has a shape in which a cut-out portion having the same shape as the cut-out portion 322d is provided to an end portion of the rectangular portion 221a of the first sealing member 221 of the display device of Embodiment 2 toward the fourth sealing member 224.

The third sealing member 323 of the display device of the present modification example has a shape in which a cut-out portion having the same shape as the cut-out portion 322d is provided to an end portion of the rectangular portion 223a of the third sealing member 223 of the display device of Embodiment 2 toward the second sealing member 222.

The fourth sealing member 324 of the display device of the present modification example has a shape in which a cut-out portion having the same shape as the cut-out portion 322d is provided to an end portion of the rectangular portion 224a of the fourth sealing member 224 of the display device of Embodiment 2 toward the third sealing member 223.

Note that the first sealing member 21, the second sealing member 22, the third sealing member 23, and the fourth sealing member 24 are preferably disposed such that widths of the ventilation holes are in a range of 0 to 1 mm. For example, the first sealing member 21 and the second sealing member 22 are preferably disposed such that, in FIG. 6, a width w7 is 0.5 mm, a width w8 is 0.5 mm, and a width w11 is 0.5 mm. Furthermore, a width W9 of FIG. 6 may be 1 mm and a width w10 may be 1 mm, for example, as shapes of the cut-out portion 322d for causing foreign matter to collect.

By using the aforementioned configuration for the sealing member of the display device of the present variation, with the display device of the present modification example, as with the display device of Embodiment 2, a ventilation hole having a path P3 that changes direction in two places can be formed, and foreign matter entering from outside more readily collects on the glue end portions (a region inside the cut-out portion 322d) of the cut-out portion 322d, as shown in FIG. 6. Accordingly, with the display device of the present modification example, ventilation holes with paths that are not linear in a plan view can be ensured, thereby preventing condensation in a space between the protective panel 3 and the display surface 11 of the display unit 1. Furthermore, by providing a region in which foreign matter collects along the paths of the ventilation holes, foreign matter can be effectively prevented from entering into a space between the display unit 1 and the protective panel 3 from outside.

### Modification Example 2

Modification Example 2 of the present embodiment is described next. Note that detailed descriptions are omitted for portions which are the same as in the above embodiments and variation.

A display device of the present modification example has a configuration in which, in the display device of Embodiment 2, the first sealing member 221 is replaced by a first sealing member 421, the second sealing member 222 is replaced with a second sealing member 422, the third sealing member 223 is replaced with a third sealing member 423, and the fourth sealing member 224 is replaced with a fourth sealing member 424, respectively. Aside from this, the display device of the present modification example is the same as the display device of Embodiment 2.

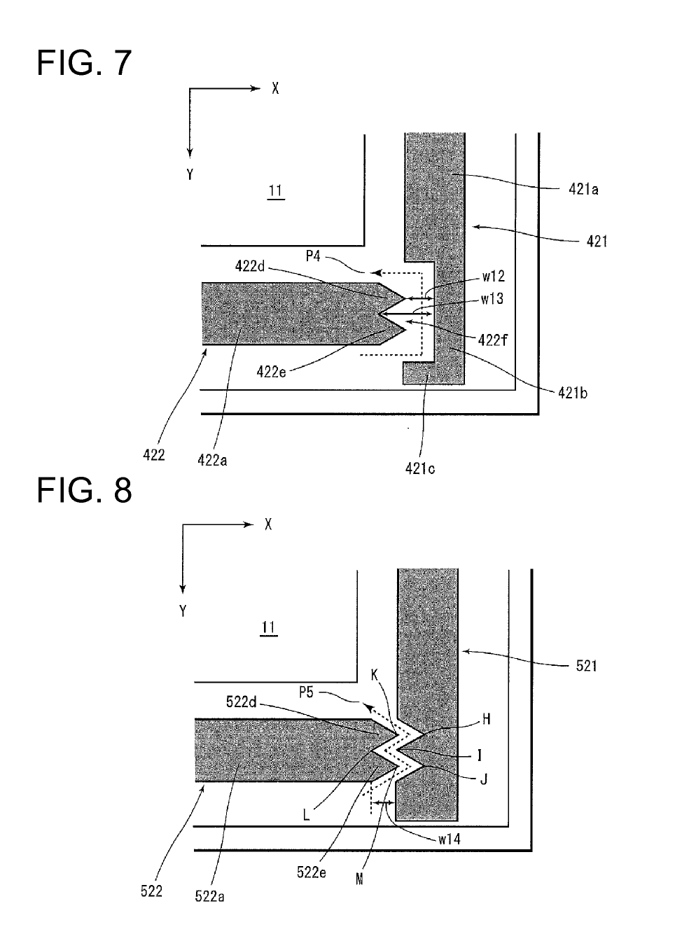

In a similar manner to FIG. 5, FIG. 7 is an enlarged view of a bottom right end portion in a plan view seen from above a display surface 11 of a display unit 1, and is a view in which a vicinity of end portions of the first sealing member 421 and the second sealing member 422 of the present variation are shown enlarged.

The second sealing member 422 of the display device of the present modification example is formed by a rectangular portion 422a, a first extended portion 422b that extends in a lengthwise direction of the rectangular portion 422a from the rectangular portion 422a, a second extended portion 422c that extends in a lengthwise direction of the rectangular portion 422a from the first extended portion 422b, and a first protruding portion 422d and a second protruding portion 422e that extend away from the first extended portion 421b of the rectangular portion 422a. Note that the first extended portion 421b and the second extended portion 421c have the same shape as the first extended portion 222b and the second extended portion 222c of Embodiment 2.

As shown in FIG. 7, the first protruding portion 422d has a shape that extends in a triangular shape from a region occupying substantially half of a top side of an end portion of the rectangular portion 422a towards the first sealing member 421 (toward the display surface 11) in the lengthwise direction of the rectangular portion 422a. Note that two end faces of the first protruding portion 422d towards the first sealing member 421 are glue end faces formed from a substance having adhesive properties.

As shown in FIG. 7, the second protruding portion 422e has a shape that extends in a triangular shape from a region occupying substantially half of a bottom side of an end portion of the rectangular portion 422a towards the first sealing member 421 (away from the display surface 11) in the lengthwise direction of the rectangular portion 422a. Note that two end faces of the second protruding portion 422e towards the first sealing member 421 are glue end faces formed from a substance having adhesive properties.

As shown in FIG. 7, the second sealing member 422 having the aforementioned shape has a triangular cut-out portion 422f on an end portion towards the first sealing member 421, and therefore foreign matter from outside readily collects in a region of this triangular cut-out portion 422f.

Note that, as one example, in FIG. 7 a width w12 may be 0.5 mm and a width w13 may be 1 mm.

Furthermore, a shape of an end portion of the first sealing member 421 towards the fourth sealing member 424 of the display device of the present modification example, a shape of an end portion of the third sealing member 423 towards the second sealing member 422, and a shape of an end portion of the fourth sealing member 424 towards the third sealing member 323 also have the same shape as the shape formed from the first protruding portion 422d and the second protruding portion 422e of the second sealing member 422 described above. Thus, a shape of a path in a plan view of ventilation holes formed between the second sealing member 422, the third sealing member 423, the fourth sealing member 424, and the first sealing member 421 is the same as the shape shown in FIG. 7.

The first sealing member 421 of the display device of the present modification example is such that a shape of an end portion of the rectangular portion 221a of the first sealing member 221 of the display device of Embodiment 2 towards the fourth sealing member 224 is a shape that is the same as the shape formed from the first protruding portion 422d and the second protruding portion 422e.

The third sealing member 423 of the display device of the present modification example is such that a shape of an end portion of the rectangular portion 223a of the third sealing member 223 of the display device of Embodiment 2 towards the second sealing member 222 of Embodiment 2 is a shape that is the same as the shape formed from the first protruding portion 422d and the second protruding portion 422e.

The fourth sealing member 424 of the display device of the present modification example is such that a shape of an end portion of the rectangular portion 223a of the third sealing member 223 of the display device of Embodiment 2 towards the second sealing member 222 of Embodiment 2 is a shape that is the same as the shape formed from the first protruding portion 422d and the second protruding portion 422e.

By using the aforementioned configuration for the sealing member of the display device of the present modification example, with the display device of the present variation, as with the display device of Embodiment 2, a ventilation hole having a path P4 that changes direction in two places can be formed, and foreign matter entering from outside more readily collects on the glue end portions (a region inside the cut-out portion 4220 of the triangular cut-out portion 422f, as shown in FIG. 7. Accordingly, with the display device of the present modification example, ventilation holes with paths that are not linear in a plan view can be ensured, thereby preventing condensation in a space between the protective panel 3 and the display surface 11 of the display unit 1. Furthermore, by providing a region in which foreign matter collects along the paths of the ventilation holes, foreign matter can be effectively prevented from entering into a space between the display unit 1 and the protective panel 3 from outside.

### Modification Example 3

Modification Example 3 of the present embodiment is described next. Note that detailed descriptions are omitted for portions that are the same as in the above embodiments and modification examples.

A display device of the present modification example has a configuration in which, in the display device of Embodiment 2, the first sealing member 421 is replaced by a first sealing member 521, the second sealing member 422 is replaced with a second sealing member 522, the third sealing member 423 is replaced with a third sealing member 523, and the fourth sealing member 424 is replaced with a fourth sealing member 524, respectively. Aside from this, the display device of the present modification example is the same as the display device of the Modification Example 2 of Embodiment 2.

In a similar manner to FIG. 5, FIG. 8 is an enlarged view of a bottom right end portion in a plan view seen from above a display surface 11 of a display unit 1, and is a view in which a vicinity of end portions of the first sealing member 521 and the second sealing member 522 of the present variation are shown enlarged.

A shape of an end portion of the second sealing member 522 of the display device of the present modification example towards the first sealing member 521 is the same shape as the second sealing member 522 of the display device of the second modification example. In other words, a first protruding portion 522d of the second sealing member 522 of the present modification example has the same shape as the first protruding portion 422d of the second sealing member 422 of Modification Example 2, and a second protruding portion 522e of the second sealing member 522 of the present modification example has the same shape as the second protruding portion 422e of the second sealing member 422 of Modification Example 2.

The first sealing member 521 of the display device of the present modification example has, in a face disposed towards the display surface 11, a shape in which a substantially identical shape as the first protruding portion 522d is cut out at the same Y coordinate position as the first protruding portion 522d, and a shape substantially identical to the second protruding portion 522e is cut out of the second protruding portion 522e at the same Y coordinate position as the second protruding portion 522e. In other words, as shown in FIG. 8, a Y coordinate (Y(K)) of a point K, which is a tip of the first protruding portion 522d of the second sealing member 522, and a Y coordinate (Y(H)) of a point H, which is a tip of a cut-out portion above (inside) the first sealing member 521, are substantially the same, and a Y coordinate (Y(M)) of a point M, which is a tip of the second protruding portion 522e of the second sealing member 522, and a Y coordinate (Y(J)) of a point J, which is a tip of a cut-out portion below (outside) the first sealing member 521, are substantially the same.

By disposing the first sealing member 521 and the second sealing member 522 having these shapes as shown in FIG. 8, a ventilation hole having a complex path (a ventilation hole having a path that bends at an acute angle in three places) can be formed between the first sealing member 521 and the second sealing member 522.

Note that, as one example, a width w14 in FIG. 8 may be 1 mm.

Furthermore, a shape of an end portion of the second sealing member 522 towards the third sealing member 523 of the display device of the present modification example, a shape of an end portion of the third sealing member 523 towards the fourth sealing member 524, and a shape of an end portion of the fourth sealing member 524 towards the first sealing member 521 also have the same shape as the shape of the end of the first sealing member 521 towards the second sealing member 522 described above. Thus, a shape of a path in a plan view of ventilation holes formed between the second sealing member 522, the third sealing member 523, the fourth sealing member 524, and the first sealing member 521 is the same as the shape shown in FIG. 8.

By using the above configuration for a sealing member of a display device of the present modification example, a ventilation hole having a path P5 that changes direction at an acute angle in three places, as shown in FIG. 8, can be formed with the display device of the present modification example. Accordingly, with the display device of the present modification example, ventilation holes with paths that are not linear in a plan view can be ensured, thereby preventing condensation in a space between the protective panel 3 and the display surface 11 of the display unit 1. Furthermore, with ventilation holes having complex paths, foreign matter can be effectively prevented from entering into a space between the display unit 1 and the protective panel 3 from outside.

### Modification Example 4

Modification Example 4 of the present embodiment is described next. Note that detailed descriptions are omitted for portions which are the same as in the above embodiments and modification examples.

A display device of the present modification example has a configuration in which, in the display device of Embodiment 3, the first sealing member 521 is replaced by a first sealing member 621, the second sealing member 522 is replaced with a second sealing member 622, the third sealing member 523 is replaced with a third sealing member 623, and the fourth sealing member 524 is replaced with a fourth sealing member 624, respectively. Aside from this, the display device of the present modification example is the same as the display device of Modification Example 3 of Embodiment 2.

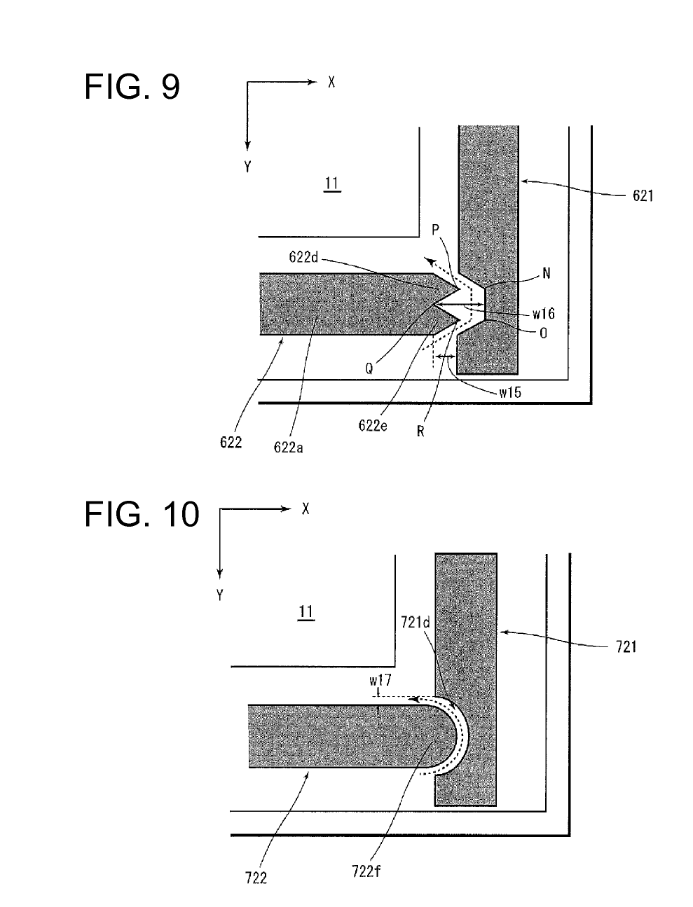

In a similar manner to FIG. 5, FIG. 9 is an enlarged view of a bottom right end portion in a plan view seen from above a display surface 11 of a display unit 1, and is a view in which a vicinity of end portions of the first sealing member 621 and the second sealing member 622 of the present modification example are shown enlarged.

A shape of an end portion of the second sealing member 622 of the display device of the present modification example towards the first sealing member 621 is the same shape as the second sealing member 422 of the display device of Modification Example 2. In other words, a first protruding portion 622d of the second sealing member 622 of the present modification example has the same shape as the first protruding portion 422d of the second sealing member 422 of Modification Example 2, and a second protruding portion 622e of the second sealing member 622 of the present variation has the same shape as the second protruding portion 422e of the second sealing member 422 of Modification Example 2.

The first sealing member 621 of the display device of the present modification example has a shape cut out substantially in a trapezoidal shape in a face disposed towards the display surface 11, as shown in FIG. 9. In other words, as shown in FIG. 9, a Y coordinate (Y(P)) of a point P, which is a tip of the first protruding portion 622d of the second sealing member 622, and a Y coordinate (Y(N)) of a point N, which is an endpoint of an upper side (inward side) of a bottom face of a cut-out portion of the first sealing member 621, are substantially the same, and a Y coordinate (Y(R)) of a point R, which is a tip of the second protruding portion 622e of the second sealing member 622, and a Y coordinate (Y(O)) of a point O, which is an endpoint of a lower side (outer side) of a bottom face of a cut-out portion of the first sealing member 621, are substantially the same.

Note that three end faces of the cut-out portions of the first sealing member 621 are glue end faces formed from a substance having adhesive properties.

Note that, as one example, in FIG. 9 a width w15 may be 1 mm and a width w16 may be 1 mm.

Furthermore, a shape of an end portion of the second sealing member 622 towards the third sealing member 623 of the display device of the present modification example, a shape of an end portion of the third sealing member 623 towards the fourth sealing member 624, and a shape of an end portion of the fourth sealing member 624 towards the first sealing member 621 also have the same shape as the shape of the end of the first sealing member 621 towards the second sealing member 622 described above. Thus, a shape of a path in a plan view of ventilation holes formed between the second sealing member 622, the third sealing member 623, the fourth sealing member 624, and the first sealing member 621 is the same as the shape shown in FIG. 9.

By disposing the first sealing member 621 and the second sealing member 622 having the above shapes as shown in FIG. 9, ventilation holes of paths that are not linear in a plan view can be formed between the first sealing member 621 and the second sealing member 622, and foreign matter entering from outside readily collects on glue faces of the cut-out portion of the first sealing member 621. Furthermore, the same is true between the third sealing member 623, the fourth sealing member 624, and the first sealing member 621.

Accordingly, with the display device of the present modification example, ventilation holes with paths that are not linear in a plan view can be ensured, thereby preventing condensation in a space between the protective panel 3 and the display surface 11 of the display unit 1. Furthermore, by providing a region in which foreign matter collects along the paths of the ventilation holes, foreign matter can be effectively prevented from entering into a space between the display unit 1 and the protective panel 3 from outside.

### Modification Example 5

Modification Example 5 of the present embodiment is described next. Note that detailed descriptions are omitted for portions which are the same as in the above embodiments and variation.

A display device of the present modification example has a configuration in which, in the display device of Embodiment 2, the first sealing member 221 is replaced by a first sealing member 721, the second sealing member 222 is replaced with a second sealing member 722, the third sealing member 223 is replaced with a third sealing member 723, and the fourth sealing member 224 is replaced with a fourth sealing member 724, respectively. Aside from this, the display device of the present modification example is the same as the display device of Embodiment 2.

In a similar manner to FIG. 5, FIG. 10 is an enlarged view of a bottom right end portion in a plan view seen from above a display surface 11 of a display unit 1, and is a view in which a vicinity of end portions of the first sealing member 721 and the second sealing member 722 of the present modification example are shown enlarged.

As shown in FIG. 10, a shape of an end portion of the first sealing member 721 towards the second sealing member 722 has a shape in which a cut-out portion 721d having a substantially semicircular shape is cut out of a rectangular shape.

As shown in FIG. 10, a shape of the second sealing member 722 towards the first sealing member 721 is a shape having an extended portion 722f that is substantially semicircular, extending in a lengthwise direction from an elongated rectangular shape. Note that a shape of an end portion of a 722 of the second sealing member towards the third sealing member 723 is the same as the shape of the end of the first sealing member 721 shown in FIG. 10. Note that a cut-out portion of the second sealing member 722 is formed inside (upward (towards a display surface 11)). Furthermore, an end portion of the first sealing member 721 towards the fourth sealing member 724 (upward) (an end portion on an opposite side away from the end portion shown in FIG. 10) is a shape that is the same as the shape of the end of the second sealing member 722 towards the first sealing member.

Note that, as one example, a width w17 in FIG. 7 may be 0.5 mm.

Furthermore, a shape of an end portion of the third sealing member 723 towards the fourth sealing member 724 of the display device of the present modification example and a shape of an end portion of the fourth sealing member 724 towards the first sealing member 721 are the same as the shape of the end portion of the first sealing member 721 towards the second sealing member 722. Furthermore, a shape of an end portion of the third sealing member 723 towards the second sealing member 722 of the display device of the present modification example and a shape of an end portion of the fourth sealing member 724 towards the third sealing member 723 are the same as the shape of the end portion of the second sealing member 722 towards the first sealing member 721. Thus, a shape of a path in a plan view of ventilation holes formed between the second sealing member 722, the third sealing member 723, the fourth sealing member 724, and the first sealing member 721 is the same as the shape shown in FIG. 10.

By disposing the first sealing member 721 and the second sealing member 722 having the above shapes as shown in FIG. 10, ventilation holes of paths (arc-shaped paths) that are not linear in a plan view can be formed between the first sealing member 721 and the second sealing member 722. Furthermore, the same ventilation holes can be formed between the third sealing member 723, the fourth sealing member 724, and the first sealing member 721.

Accordingly, with the display device of the present modification example, ventilation holes with paths (arc-shaped paths) that are not linear in a plan view can be ensured, thereby preventing condensation in a space between the protective panel 3 and the display surface 11 of the display unit 1. Furthermore, by providing a region in which foreign matter collects along the paths of the ventilation holes, foreign matter can be effectively prevented from entering into a space between the display unit 1 and the protective panel 3 from outside.

### OTHER EMBODIMENTS

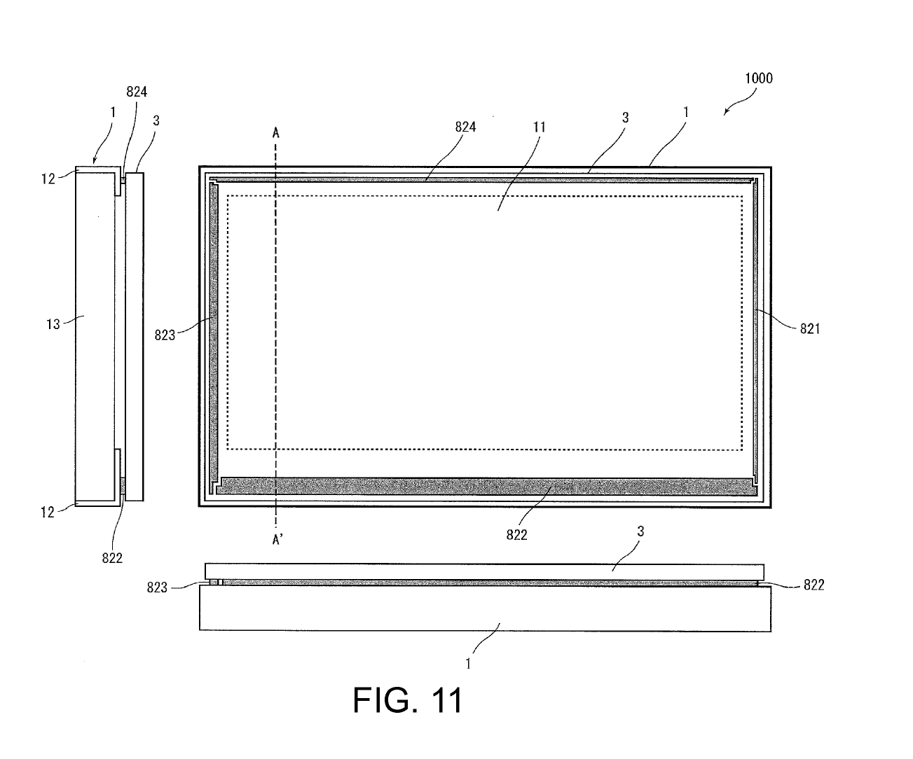

In the above embodiments, a case in which widths of a first sealing member, a second sealing member, a third sealing member, and a fourth sealing member of a sealing member 2 are substantially equal was described, but without being limited thereto, it is also possible for the widths of the first sealing member, the second sealing member, the third sealing member, and the fourth sealing member to be different. For example, the widths of the first sealing member, the second sealing member, the third sealing member, and the fourth sealing member in a plan view may differ as shown in FIG. 11. FIG. 11 is a view showing one example of a display device 1000, a plan view seen from above a display surface 11 of the display device 1000, and a cross-sectional view (at the bottom) along a line AA′ of a frontal view (to the left) and the frontal view. As shown in FIG. 11, the display device 1000 is provided, for example, with a display unit 1 formed by fitting a liquid crystal unit (or an organic EL unit) 13 into a frame (bezel) 12 that secures the liquid crystal unit (or the organic EL unit) 13, a protective panel 3 (or a touch panel), and a first sealing member 821, a second sealing member 822, a third sealing member 823, and a fourth sealing member 824 that are disposed so as to surround a display surface 11 between the display unit 1 and the protective panel 3.

FIG. 11 shows an example of a case in which ventilation holes as in Embodiment 1 are formed between the first sealing member 821, the second sealing member 822, the third sealing member 823, and the fourth sealing member 824 in a case in which widths of the first sealing member 821, the second sealing member 822, the third sealing member 823, and the fourth sealing member 824 differ. As shown in FIG. 11, shapes of end portions of the first sealing member 821, the second sealing member 822, the third sealing member 823, and the fourth sealing member 824 may be selected such that an inner region surrounded by the sealing member in a plan view and an outer region form ventilation holes, as in Embodiment 1, in accordance with the widths of the first sealing member 821, the second sealing member 822, the third sealing member 823, and the fourth sealing member 824.

Furthermore, it is also possible to apply the embodiments other than Embodiment 1 and the modification examples to the widths of the first sealing member, the second sealing member, the third sealing member, and the fourth sealing member. In this case, too, in a similar manner to the case shown in FIG. 11, shapes of the end portions of the first sealing member, the second sealing member, the third sealing member, and the fourth sealing member may be selected in accordance with the widths thereof so as to form ventilation holes similar to those shown in the embodiments and the modification examples.

Furthermore, when manufacturing display devices shown in the embodiments and the modification examples, the sealing member 2 may be adhered to the protective panel 3 after being adhered to the display unit 1, or the sealing member 2 may be adhered to the display unit 1 after being adhered to the protective panel 3.

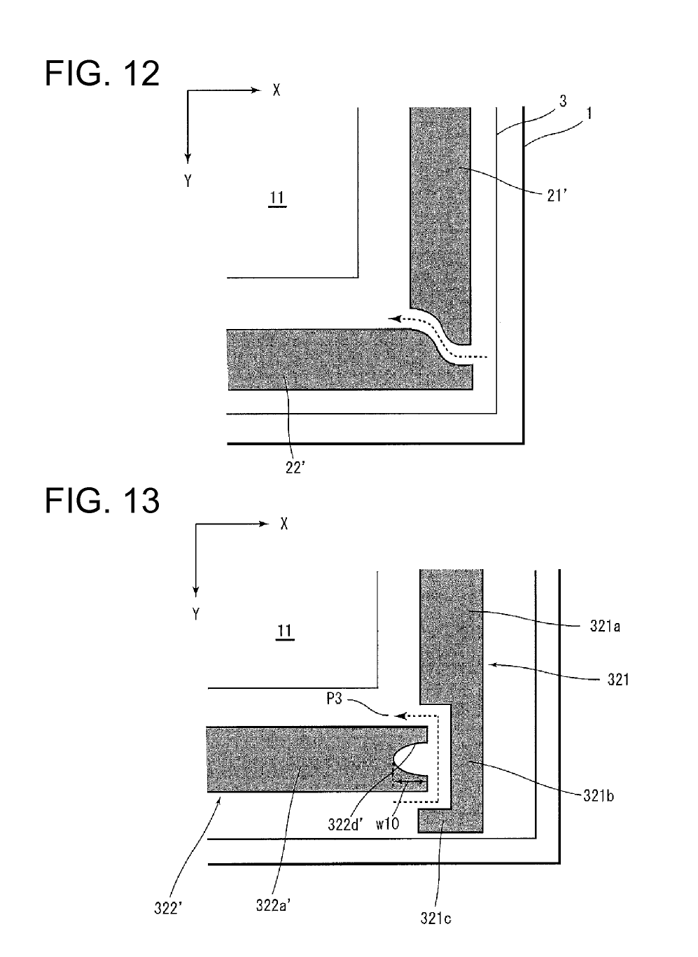

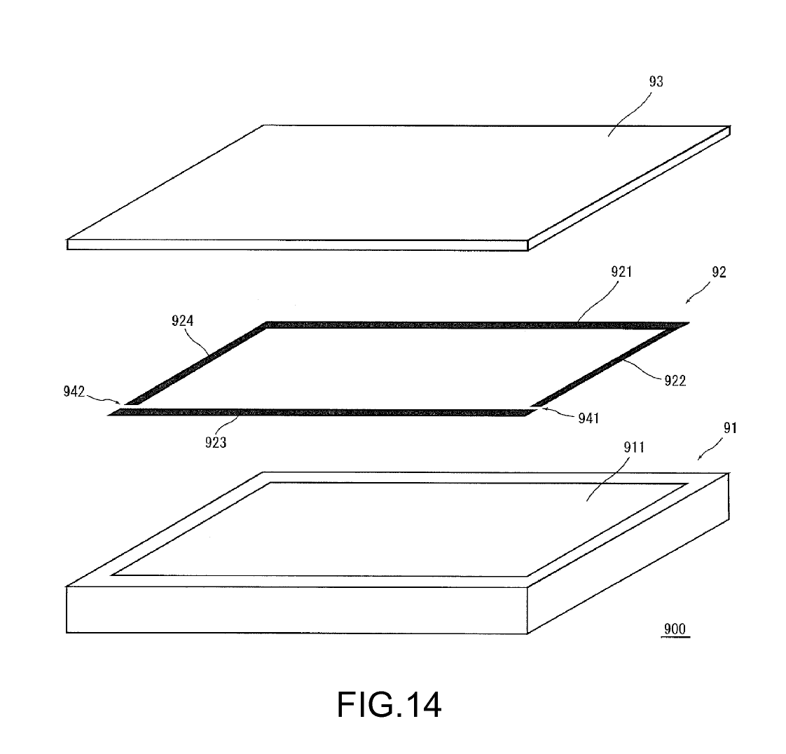

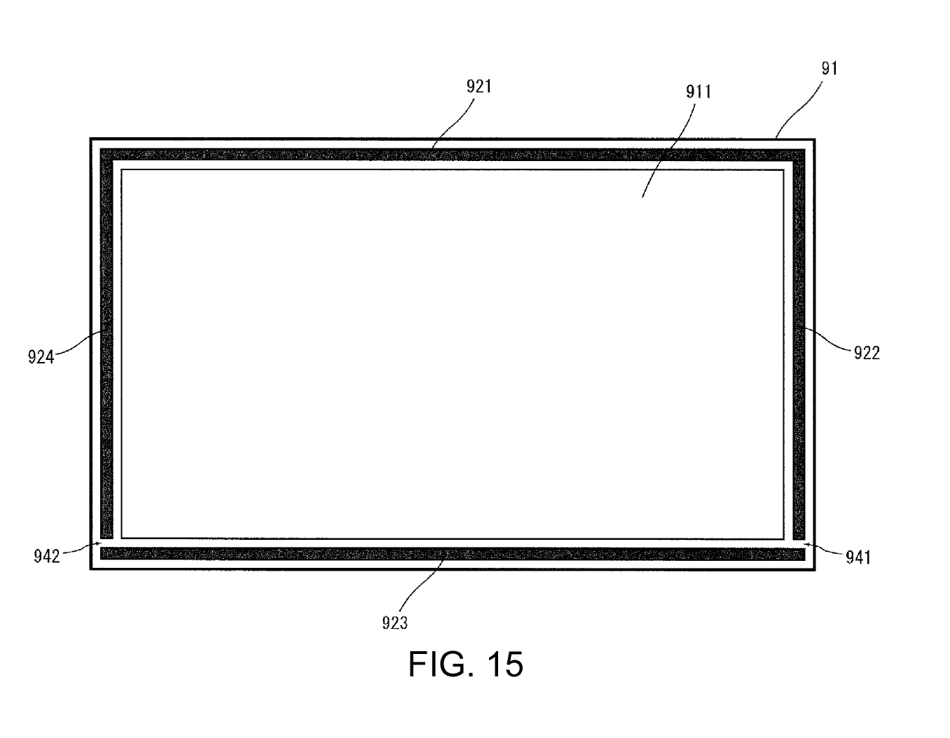

Furthermore, in Embodiment 1, a case in which ventilation holes having step-shaped paths in a plan view are formed was described, but without being limited to this, it is possible to use a shape in which end portions of the first sealing member, the second sealing member, the third sealing member, and the fourth sealing member of the sealing member 2 are rounded. Thus, for example, as shown in FIG. 12, a path of a ventilation hole can be formed substantially in an S-shape by a first sealing member 21′ and a second sealing member 22′ in which end portions are rounded. Furthermore, it is also possible to round end portions of the first sealing member, the second sealing member, the third sealing member, and the fourth sealing member of the sealing member 2 in the embodiments other than Embodiment 1 and the modification examples.

Furthermore, it is also possible to use a shape in which regions provided along ventilation holes in which foreign matter from outside collects are rounded. For example, it is also possible to form the rectangular cut-out portion 322d shown in FIG. 6 as a cut-out portion 322d′ having a substantially semielliptical shape as shown in FIG. 13. Furthermore, the cut-out portion may be a substantially semicircular shape.

Furthermore, in Modification Example 3 of Embodiment 2, a case was described in which a ventilation hole having a path that bends three times at an acute angle is formed was described, but without being limited to this, it is also possible, for example, for ventilation holes having paths that bend an odd number of times to be formed.

Furthermore, in the above embodiments, expressions such as “substantially the same,” “substantially equal,” and the like were used, and these include discrepancies and design errors that occur when control or the like is performed so as to achieve “equality” as a target value (or a design value), or errors or the like determined by resolution, and are concepts including a range in which a person skilled in the art judges (recognizes) as “equal.”

Furthermore, expressions such as “substantially the same shape,” “substantially half,” “substantially trapezoidal,” “substantially semicircular,” and the like were used regarding shapes, and these are concepts that allow for an error range and a range recognized by a person skilled in the art, as above.

Furthermore, in the above embodiments, of configuration members, only main members required for the embodiments are shown in a simplified manner. Accordingly, other constituent members not explicitly shown in the embodiments may be provided. Furthermore, in the embodiments and drawings, dimensions of members do not necessarily faithfully represent actual dimensions or dimensional ratios, etc. Accordingly, modifications to dimensions and dimensional ratios, etc., are possible within a range that does not depart from the gist of the present invention.

Note that a concrete configuration of the present invention is not limited to the embodiments described above, and may be modified or corrected in various ways within a range that does not depart from the gist of the invention.

### INDUSTRIAL APPLICABILITY

The present invention has industrial applicability as a display device provided with a capacitive or other type of touch panel and a protective panel.

### DESCRIPTION OF THE REFERENCE CHARACTERS

| | |
|---|---|
| 1000 | display device |
| 1 | display unit |
| 11 | display surface |
| 2 | sealing member |
| 21, 221, 321, 421, 521, 621, 721 | first sealing member |
| 22, 222, 322, 422, 522, 622, 722 | second sealing member |
| 23, 223, 323, 423, 523, 623, 723 | third sealing member |
| 24, 224, 324, 424, 524, 624, 724 | fourth sealing member |
| 3 | protective panel (protective portion) |

1. A display device, comprising:
a display unit having a display surface;
a protective unit disposed so as to cover said display surface; and
a sealing member provided between said display unit and said protective unit,
wherein the sealing member surrounds the display surface in a plan view and is provided with a non-linear shaped path that connects an inner region surrounded by said sealing member to an outer region outside the sealing member.

2. The display device according to claim 1,
wherein the display surface is rectangular,
wherein said sealing member includes a first sealing member, a second sealing member, a third sealing member, and a fourth sealing member disposed outside respective edges of four edges of said display surface in a plan view, and
wherein, in at least one space of a space between the first sealing member and the second sealing member, a space between the second sealing member and the third sealing member, a space between the third sealing member and the fourth sealing member, and a space between the fourth sealing member and the first sealing member in a plan view, the path has a shape that bends twice at a right angle so as to connect, to the outer region, the inner region collectively surrounded by said first sealing member, said second sealing member, said third sealing member, and said fourth sealing member.

3. The display device according to claim 1,
wherein the display surface is rectangular,
wherein said sealing member includes a first sealing member, a second sealing member, a third sealing member, and a fourth sealing member disposed outside respective edges of four edges of said display surface in a plan view, and
wherein, in at least one space of a space between the first sealing member and the second sealing member, a space between the second sealing member and the third sealing member, a space between the third sealing member and the fourth sealing member, and a space between the fourth sealing member and the first sealing member in a plan view, the path has a shape that bends an odd number of times at an acute angle as to connect, to the outer region, the inner region collectively surrounded by said first sealing member, said second sealing member, said third sealing member, and said fourth sealing member.

4. The display device according to claim 1,
wherein the display surface is rectangular,
wherein said sealing member includes a first sealing member, a second sealing member, a third sealing member, and a fourth sealing member disposed outside respective edges of four edges of said display surface in a plan view,
wherein a first end of the first sealing member is disposed near a second end of the second sealing member,
wherein a first end of the second sealing member is disposed near a second end of the third sealing member,
wherein a first end of the third sealing member is disposed near a second end of the fourth sealing member,
wherein a first end of the fourth sealing member is disposed near a second end of the first sealing member, and
wherein at least one of the following is satisfied:
(1) the first sealing member has a substantially trapezoidal cut-out portion in the first end, and the second sealing member has a triangular cut-out portion in a region facing the substantially trapezoidal cut-out portion of the first sealing member;
(2) the second sealing member has a substantially trapezoidal cut-out portion in the first end, and the third sealing member has a triangular cut-out portion in a region facing the substantially trapezoidal cut-out portion of the second sealing member;
(3) the third sealing member has a substantially trapezoidal cut-out portion in the first end, and the fourth sealing member has a triangular cut-out portion in a region facing the substantially trapezoidal cut-out portion of the third sealing member; and
(4) the fourth sealing member has a substantially trapezoidal cut-out portion in the first end, and the first sealing member has a triangular cut-out portion in a region facing the substantially trapezoidal cut-out portion of the fourth sealing member.

5. The display device according to claim 1, wherein the sealing member is provided so as to surround the display surface in a plan view and to define the path so as to connect, in a substantially arc-like shape, the inner region surrounded by the sealing member to the outer region outside the sealing member.

6. The display device according to claim 1, wherein the sealing member is provided so as to surround the display surface in a plan view and to define the path so as to connect, in a substantially “S”-like shape, the inner region surrounded by the sealing member to the outer region outside the sealing member.

7. The display device according to claim 1,
wherein the display surface is rectangular,
wherein said sealing member includes a first sealing member, a second sealing member, a third sealing member, and a fourth sealing member disposed outside respective edges of four edges of said display surface in a plan view,
wherein a first end of the first sealing member is disposed near a second end of the second sealing member,
wherein a first end of the second sealing member is disposed near a second end of the third sealing member,
wherein a first end of the third sealing member is disposed near a second end of the fourth sealing member,
wherein a first end of the fourth sealing member is disposed near a second end of the first sealing member, and
wherein at least one of the following is satisfied:
(1) the first sealing member has a substantially rectangular cut-out portion in the first end, and the second sealing member has a semielliptical cut-out portion in a region facing the substantially rectangular cut-out portion of the first sealing member;
(2) the second sealing member has a substantially rectangular cut-out portion in the first end, and the third sealing member has a semielliptical cut-out portion in a region facing the substantially rectangular cut-out portion of the second sealing member;
(3) the third sealing member has a substantially rectangular cut-out portion in the first end, and the fourth sealing member has a semielliptical cut-out portion in a region facing the substantially rectangular cut-out portion of the third sealing member; and
(4) the fourth sealing member has a substantially rectangular cut-out portion in the first end, and the first sealing member has a semielliptical cut-out portion in a region facing the substantially rectangular cut-out portion of the fourth sealing member.

8. The display device according to claim 1,
wherein the display surface is rectangular,
wherein said sealing member includes a first sealing member, a second sealing member, a third sealing member, and a fourth sealing member disposed outside respective edges of four edges of said display surface in a plan view,
wherein, in at least one space of a space between the first sealing member and the second sealing member, a space between the second sealing member and the third sealing member, a space between the third sealing member and the fourth sealing member, and a space between the fourth sealing member and the first sealing member in a plan view, the path connects, to the outer region, the inner region collectively surrounded by said first sealing member, said second sealing member, said third sealing member, and said fourth sealing member, and
wherein when a first width is a width of a first position at which the path is connected to the inner region collectively surrounded by the first sealing member, the second sealing member, the third sealing member, and the fourth sealing member, and when a second width is a width of a second position at which the path is connected to the outer region outside the first sealing member, the second sealing member, the third sealing member, and the fourth sealing member in a plan view, the path has a width that is greater than whichever of the first width or the second width is wider in at least one portion between the first position and the second position in a plan view.
